(19) United States
(12) Patent Application Publication
(10) Pub. No.: US 2007/0230152 A1
(43) Pub. Date: Oct. 4, 2007

(54) Electronic circuit device and shelf for receiving electronic circuit boards of the electronic circuit device

(75) Inventor: Hiroaki Abe, Kawasaki (JP)

Correspondence Address: BINGHAM MCCUTCHEN LLP, 2020 K Street, N.W., Intellectual Property Department, WASHINGTON, DC, 20006, US

(73) Assignee: Fujitsu Limited

(21) Appl. No.: 11/444,336

(22) Filed: Jun. 1, 2006

(30) Foreign Application Priority Data
Mar. 30, 2006 (JP) 2006-092853

(51) Int. Cl. H05K 7/14

(52) U.S. Cl. 361/796; 361/788

(57) ABSTRACT

A shelf for receiving a plurality of electronic circuit boards, the electronic circuit boards having a structure where a connecter installing part is provided at a front end part of each of the boards and an optical transmitting and receiving element for optical communications between two or more of the electronic circuit boards is provided at a rear end part of each of the boards, includes a plurality of connectors arranged on a backboard of the shelf, the shelf having a right hexahedral-shaped configuration, the connectors detachably supporting the connecter installing parts of the electronic circuit boards; and a bonnet attached to a front surface opening part of the shelf so as to form a closed space, the bonnet having a mirror surface situated at a rear surface of the bonnet so that an optical communication signal being received and transmitted between two or more of the electronic circuit boards is reflected.

### BACKGROUND OF THE INVENTION

1. Field of the Invention

The present invention generally relates to electronic circuit devices and shelves for receiving electronic circuit boards of the electronic circuit devices, and more specifically, to an electronic circuit device having plural connectors, plural electronic circuit boards detachably supported by the connectors, and a bonnet attached to an opening part of a shelf so as to form a closed space, the shelf receiving the electronic circuit boards of the electronic circuit device. Here, the connectors are arranged at a backboard of the shelf, the shelf having a solid rectangular-shaped configuration.

2. Description of the Related Art

Generally, a large or medium sized communication device or computer device has a electronic circuit device with a shelf where plural electronic circuit boards (cards) are installed. FIG. 1 is a perspective view of a related art electronic circuit device 50 forming a communication device.

Referring to FIG. 1, a shelf 51 is made of an aluminum alloy and has a six-face rectangular-shaped configuration (right hexahedral configuration). Plural connectors (not shown in FIG. 1) are provided at a shelf rear surface side backboard (backplane) 52. Electronic circuit boards 61 through 68 are connected to the connectors. A bonnet 53 covers an opening part situated at a front surface of the shelf 51. The bonnet 53 together with the shelf 51 protects electronic circuits from a noise (electromagnetic wave) and prevents electromagnetic radiation of the electronic circuits from emanating to the outside. In FIG. 1, an upper surface of the shelf 51 and the backboard 52 are indicated transparently so that the board structure inside the shelf can be seen.

In this example, a monitoring board 61 collects various monitoring information from monitored boards 62 through 68 so as to transfer the information to a host device. The monitored boards 62 through 68 perform communication control of a device main body, detect various states with respect to the communications, and report the detected states to the monitoring board 61. Since the monitored boards 62 through 68 process extremely weak signals with respect to radio communication, the noise generated in the transmission of a high speed digital signal should be avoided as much as possible. Because of this, a bus line structure is not applied to the backboard 52. In the backboard 52, wirings for signal transmission are individually provided between the monitoring board 51 and each of the monitored boards 62 through 68 so that the monitoring information is collected.

However, recently and continuing, in such an electronic circuit device, as a system has a high function and becomes complex, the number of signals transferred between the boards is drastically increased so that it is desirable that more signals be transferred at high speed and with low noise.

In the meantime, Japanese Laid-Open Patent Application Publication No. 9-284229 discloses a closed space optical transmission system having a bidirectional optical transmission communication system provided among various sensor units or information units such as a switch, displayer, printer or the like and a control unit for controlling the sensor units or information units so that a complex wiring process is simplified.

However, in the above-discussed related art, basically, it is necessary to secure an optical path for directly performing optical communications between each of the sensor units and a common control unit. Therefore, efficiency of use of the closed space for the optical communications is low and also there is limitation to the degree of freedom of the arrangement of the units.

### SUMMARY OF THE INVENTION

Accordingly, embodiments of the present invention may provide a novel and useful electronic circuit device and shelf for receiving electronic circuit boards, solving one or more of the problems discussed above.

One aspect of the present invention may be to provide an electronic circuit device whereby a large amount of information can be efficiently transferred among boards with low noise and a shelf for receiving electronic circuit boards of the electronic circuit device.

According to the embodiments of the present invention, a shelf for receiving a plurality of electronic circuit boards, the electronic circuit boards having a structure where a connecter installing part is provided at a front end part of each of the boards and an optical transmitting and receiving element for optical communications between two or more of the electronic circuit boards is provided at a rear end part of each of the boards, including a plurality of connectors arranged on a backboard of the shelf, the shelf having a right hexahedral-shaped configuration, the connectors detachably supporting the connecter installing parts of the electronic circuit boards; and a bonnet attached to a front surface opening part of the shelf so as to form a closed space, the bonnet having a mirror surface situated at a rear surface of the bonnet so that an optical communication signal being received and transmitted between two or more of the electronic circuit boards is reflected, is provided.

According to the embodiments of the present invention, an electronic circuit device, including: a plurality of connectors arranged on a back board of a shelf, the shelf having a right hexahedral-shaped configuration; a plurality of electronic circuit boards detachably supported by the connectors; and a bonnet attached to a front surface opening part of the shelf so as to form a closed space; wherein a mirror surface is provided at a rear surface of the bonnet; and optical transmitting and receiving elements are provided at bonnet sides of the electronic circuit boards so that optical communications are performed between two or more of the electronic circuit boards by using light reflected by the mirror surface, is also provided.

According to the above-mentioned electronic circuit device and shelf for receiving electronic circuit boards, by using a vacant space at the shelf front surface, it is possible to transfer a large amount of data at high speed with low noise so that high functionality and improved reliability of the electronic circuit device can be achieved.

Other objects, features, and advantages of the present invention will be come more apparent from the following detailed description when read in conjunction with the accompanying drawings.

### BRIEF DESCRIPTION OF THE DRAWINGS

FIG. 1 is a perspective view of a related art electronic circuit device;

FIG. 2 is a perspective view of an electronic circuit device of an embodiment of the present invention;

FIG. 3 is a cross-sectional view of a bonnet of the embodiment of the present invention;

FIG. 4 is a first diagram for explaining an optical communication method of the embodiment of the present invention;

FIG. 5 is a second diagram for explaining an optical communication method of the embodiment of the present invention; and

FIG. 6 is a perspective view of an electronic circuit device of another embodiment of the present invention.

### DETAILED DESCRIPTION OF THE PREFERRED EMBODIMENTS

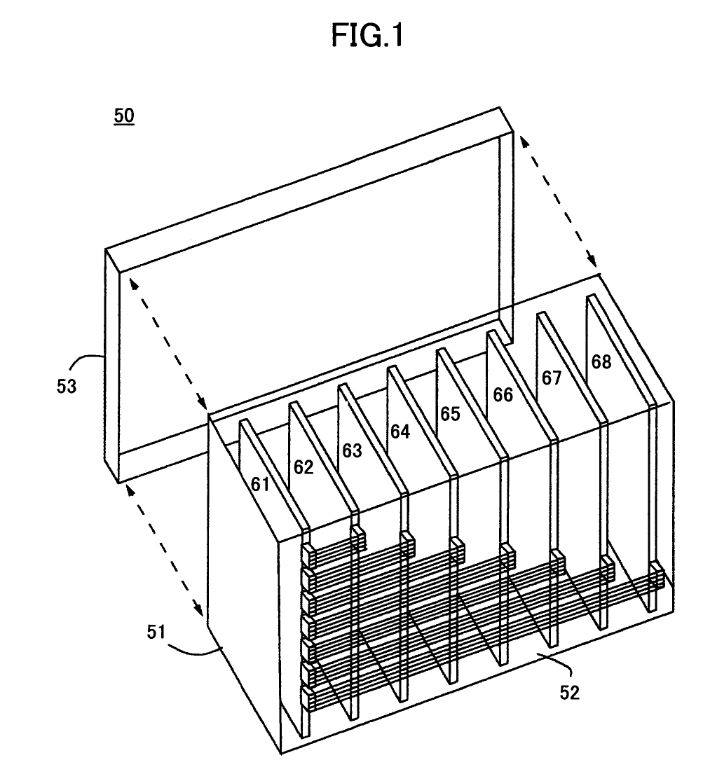

A description is given below, with reference to the FIG. 1 through FIG. 15 of embodiments of the present invention.

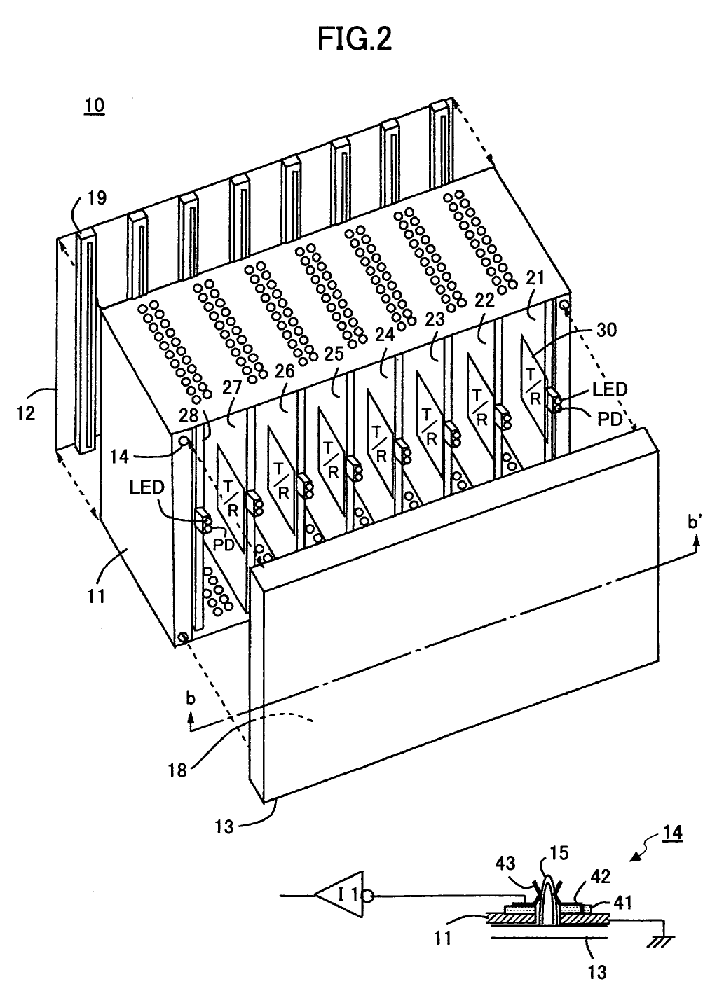

FIG. 2 is a perspective view of an electronic circuit device of an embodiment of the present invention. A case where the rear surface of a bonnet is a plane surface is shown in FIG. 2.

Referring to FIG. 2, an electronic circuit device 10 performs communication control of a radio network. A shelf 11 is made of an aluminum alloy and has a right hexahedral configuration. A backboard (backplane) 12 is provided at the rear surface of the shelf 11. Connectors 19 are fixed to the backboard 12.

A bonnet 13 having a flat box-shaped configuration is attached to an opening part situated at the front surface of the shelf 11. A mirror surface 18 is provided at the bonnet 13 rear surface. Bonnet attaching holes 14 are formed at four corners of the shelf 11 front surface. Electronic circuit boards 21 through 28 form a communication control device.

A monitoring board 21 collects various monitoring information with respect to communication control from monitored boards 22 through 28 so as to transfer the information to a host device. The monitored boards 22 through 28 perform the communication control of a device main body, detect various states with respect to the communications, and report the detected states to the monitoring board 21.

Infrared light emitting diodes (LEDs) and infrared light receiving photo diodes (PDs) are provided at rear ends of the boards 21 through 28. Optical transmitting and receiving circuits (T/R) 30 perform optical communication of the monitoring information among the boards.

Plural connectors 19 are provided at designated distances on the backboard 12. The entire backboard 12 is fixed to the rear surface of the shelf 11. For convenience, in FIG. 2 the connectors 19 can be seen. Although not shown in FIG. 2, an electric power line for feeding to the connectors 19 and a GND line and a wiring of a main signal with respect to network communications are provided on the rear surface of the backboard 19.

On the other hand, transferring and receiving information with respect to network monitoring is performed via an optical communication part provided at the shelf 11 front surface side, namely the rear edge parts of the boards 21 through 28. The mirror surface 18 is provided at the rear surface of the bonnet 13 for performing optical communication smoothly and with high reliability. By attaching the bonnet 13 using the bonnet attaching holes 14 situated at the front surface of the shelf 11, it is possible to form an optical transmission path in the vacant space at the rear surface of the bonnet 11. As the mirror surface 18 for reflecting the infrared light, a glass plate, an acrylic plate, a glass plate (mirror) having a back surface where silver (Ag) plating is applied, a plastic plate having a surface where chrome plating is applied, or a polished surface of metal such as aluminum (Al), stainless, or brass may be used.

An inserted drawing (a) in FIG. 2 shows a cross-sectional structure for attaching the bonnet 13 to the shelf 11 via the bonnet attaching holes 14. Mounting of the bonnet 13 is performed by pushing metal elastic convex parts 15 situated at four corners of the bonnet 13 rear surface into the corresponding attaching holes 14 situated at the front surface of the shelf 11. Spring contacts 42 and 43 are fixed to the attaching hole 14. The spring contact 42 is connected to ground of the shelf 11 via an insulation board 41. The spring contact 43 is connected to an input of an inverter circuit 11. By pushing the metal convex part 15 in an intermediate part of the spring contacts 42 and 43, conduction between the spring contacts 42 and 43 can be achieved and attachment of the bonnet 13 can be detected. Opening and closing the bonnet 13 may be detected by mutual operation of a magnetic field of a permanent magnet provided at a side of the bonnet 13 and a lead switch provided at a side of the shelf 11.

Thus, since the bonnet 13 is detachably provided, it is possible to easily perform maintenance against stains and degradation of the mirror surface. In addition, even if the device is working, by removing the bonnet 13, it is possible to easily perform the maintenance of the electronic circuit boards or change a wire without affecting the working of the device.

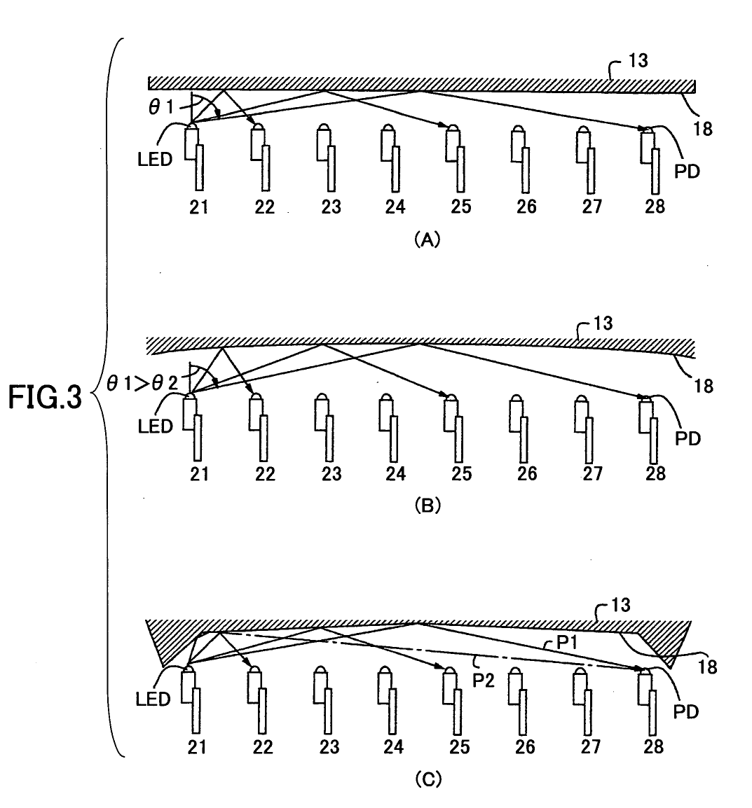

FIG. 3 is a cross-sectional view of the space part of the bonnet 13 rear surface taken along a line b-b′ in FIG. 1.

FIG. 3-(A) shows a case where the mirror surface 18 is a plane surface. Signal lights emitted from the LEDs at various injection angles θ are reflected by the mirror surface 18 and then input to the photodiodes PDs of all of the boards 22, 25, 28, and others. In this case, while an injection angle θ1 of a light going to the PD of the furthest board 28 is relatively large, it is possible to perform the communications by using an LED and a PD having wide directivities. This can be applied to a case where the LED of the boards 22 through 28 emit. Thus, by effectively using the mirror surface 18 of the rear surface of the bonnet 13, it is possible to perform optical communications between two or more of the boards 22 through 28.

FIG. 3-(B) shows a case where the mirror surface 18 is a concave surface perpendicular to (the concavity is away from) a board arrangement direction. By the mirror surface 18 having a concave-shaped configuration, injected lights from the LEDs are easily concentrated (reflected) in the center of the closed space. In addition, since the distance between the optical transmitting and receiving elements and the mirror surface is long in the vicinity of the center of the mirror surface 18, relay of the light using the mirror reflection can be easily performed. In other words, even if the light is injected at an injection angle θ2 smaller than the LED injection angle θ1 of the monitoring board 21 (θ2<θ1), the light is reflected by the center part of the mirror surface 18 so as to be properly received by the PD of an opposite side monitored board 28. Therefore, even if the directivity of the LED or the PD is not so large, it is possible to perform the optical communications with high reliability in the entirety of the closed space.

FIG. 3-(C) shows a case where a mirror surface 18 of a part facing the light transmitting and receiving elements of a both edge part board 13 has a high angle. In this example, since the injected light from the LED of the monitoring board 21 passes through plural optical paths P1 and P2 to be received by the PD of the board 28, the reliability of the optical communications is improved.

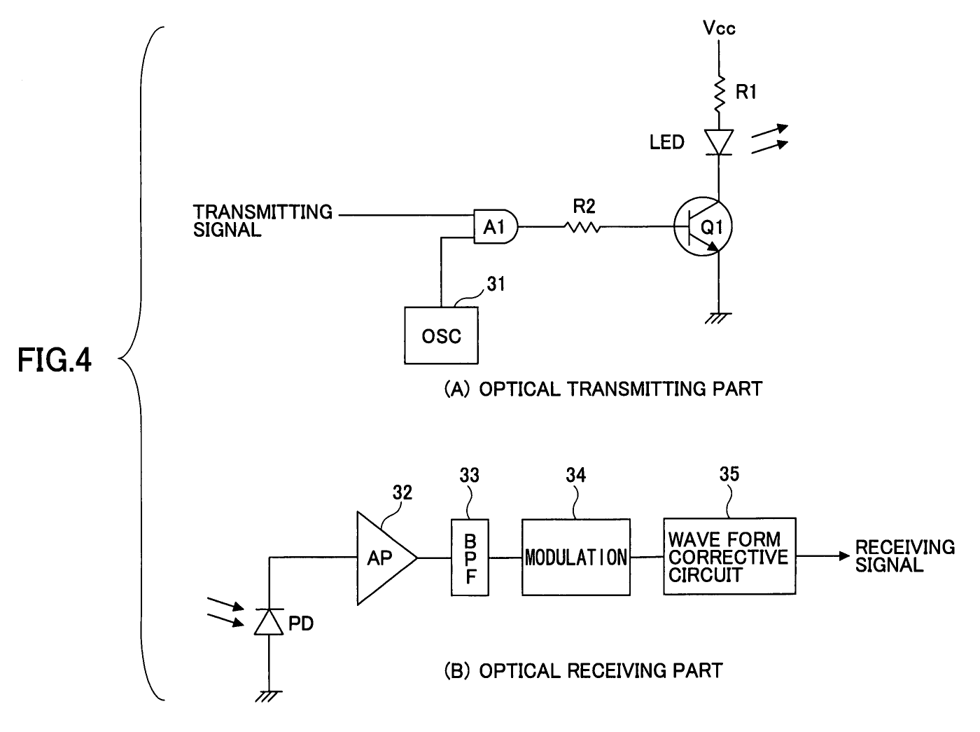

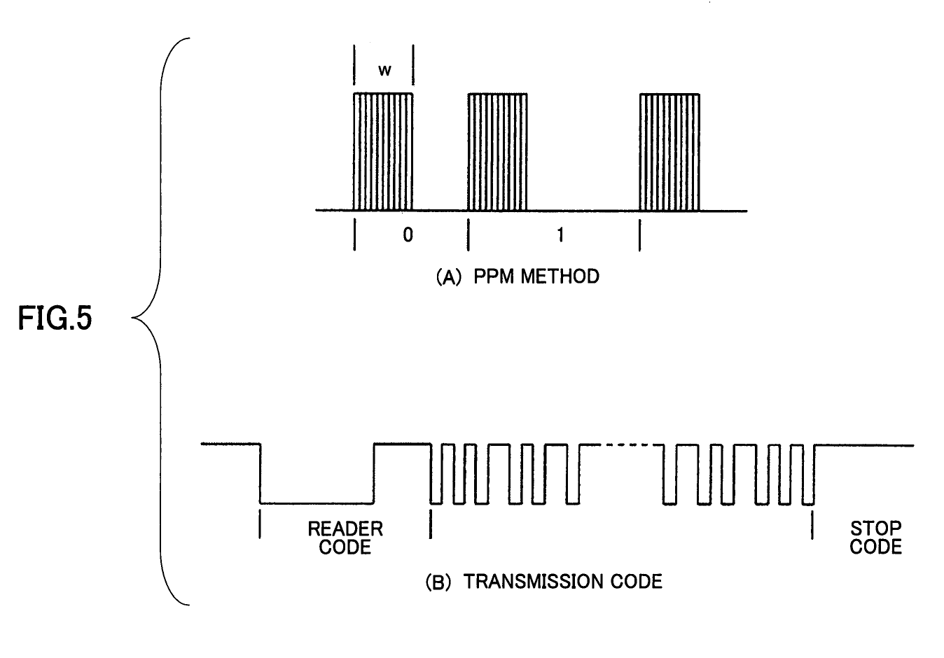

FIG. 4 is a first diagram for explaining an optical communication method of the embodiment of the present invention. FIG. 5 is a second diagram for explaining an optical communication method of the embodiment of the present invention. In the embodiment of the present invention, an optical communication method used in a remote control device coming into the market is applied. Therefore, it is possible to perform the maintenance of the electronic circuit boards by employing a widely used remote controller.

FIG. 4-(A) is a circuit diagram of the optical transmitting part. In FIG. 4-(A), an AND gate circuit A1 amplitude-modulates an outgoing signal (38 through 40 kHz) of an oscillating circuit (OSC) 31 by an incoming base band signal and a transistor Q1 is driven by its output so that a pulse-modulated optical signal is output from the LED. The output light of the LED is amplitude-modulated at a high frequency so that influence of exotic optical noise is reduced.

FIG. 5-(A) shows a Pulse Position Modulation (PPM) type optical pulse signal. The pulse signal of approximately 38 through 40 kHz continues for a designated time interval w. A pulse gap in data “0” is different from a pulse gap in data “1”.

FIG. 4-(B) is a circuit diagram of the optical receiving part. Referring to FIG. 4-(B), “PD” represents a photodiode having sensitivity against infrared. An amplifier circuit (AP) 32 converts an extremely weak optical detection electrical current to a voltage signal so that amplification is achieved. A band pass filter (BPF) 33 is provided through which a reception component of 38 through 40 kHz passes. A demodulation circuit 34 demodulates a received base band signal. A wave form corrective circuit 35 corrects the demodulated output so as to generate the transmitting base band signal.

FIG. 5-(B) shows a transmission format of transmitting/receiving base band signals. First, a reader code is transmitted and then an identification (ID) code of a destination electronic circuit board is transmitted. Furthermore, a command of Pauling control or a response signal (monitoring information and others) follows and last a stop code of a high level equal to or higher than 30 ms is added.

Under this structure, the optical communications among the monitoring board 21 and the monitored boards 22 through 28 are performed by the Pauling control of the monitoring board 21. Therefore, it is possible to perform efficient optical network communication effectively using a single closed space at the bonnet 13 rear surface.

While the Pauling type optical communication control is discussed in the above example, the present invention is not limited to this. For example, the optical communications between plural boards may use a Carrier Sense Multiple Access with Collision Detection (CSMA/CD) type which is commonly used in Ethernet communications. In this case, exchanging information between any two boards may be performed without providing a network control board.

In other words, in the board that is used for data transmission, a method may be used wherein transmission is started from a designated burst frame pattern based on confirmation of not receiving the light, then the received light is received and demodulated by the optical receiving part during the frame transmission, and the received or transmitted contents are compared with time so that generation or existence of collision is detected. Alternatively, a method may be used wherein a received light level during the data transmission is observed and the collision is detected when the level exceeds a designated threshold value. When the collision is detected during the frame transmission, the transmission is immediately cut off and transmitting of the burst frame is restarted after a random time delay. On the other hand, only the frame normally received is taken in the receiving side board and the frame of the received error is destroyed.

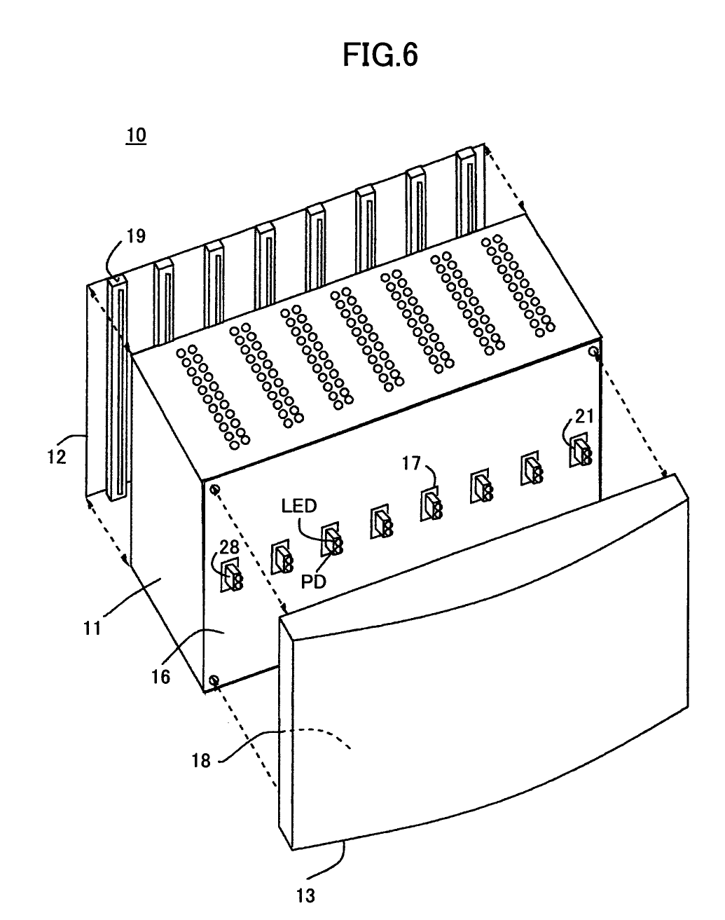

FIG. 6 is a perspective view of an electronic circuit device of another embodiment of the present invention. In this example, the mirror surface 18 situated at the rear surface of the bonnet 13 has a concave surface perpendicular to a board arrangement direction. A relay member 16 is provided between the mirror surface 18 and an opening part of the shelf 11. The relay member 16 has windows corresponding to the optical transmitting and receiving elements, that is, the LEDs and the PDs of the boards 21 through 28. The relay member 16 is made of an aluminum (Al) plate and preferably has a surface side which is mirror-coated. As discussed above, the windows 17 are formed as corresponding to the optical transmitting and receiving elements. Under this structure, the mirror surface 18 situated at the rear surface of the bonnet 13 and a surface of the relay member 16 can form an efficient light reflection transferring path so that an optical communications system having high reliability can be made.

The present invention is not limited to these embodiments, but variations and modifications may be made without departing from the scope of the present invention.

For example, while infrared optical communications are discussed in the above embodiments, the present invention is not limited to this. The present invention can be applied to optical communications using visible light.

In addition, while the example is used where the reflection surface made of glass is used as the mirror surface, the present invention is not limited to this. In addition, for example, frosted glass whose surface is scattering-processed or a thick opaque white color acrylic plate may be used as a scattered plate of the signal lights. In this case, an injection light of the LED is scattered in all directions so that the scattered light is widely spread in the opaque white color acrylic plate. As a result of this, it is possible to make the entirety of the acrylic plate light. Alternatively, light may be irradiated on gas supplied in a glass tube.

Thus, according to the above-discussed embodiment of the present invention, a shelf 11 for receiving a plurality of electronic circuit boards, the electronic circuit boards having a structure where a connecter 19 installing part is provided at a front end part of each of the boards and an optical transmitting and receiving element LED, PD for optical communications between two or more of the electronic circuit boards 21 through 28 is provided at a rear end part of each of the boards, the shelf including: a plurality of connectors 19 arranged on a backboard of the shelf, the shelf having a right hexahedral-shaped configuration, the connectors detachably supporting the connecter installing parts of the electronic circuit boards; and a bonnet 13 attached to a front surface opening part of the shelf so as to form a closed space, the bonnet having a mirror surface 18 situated at a rear surface of the bonnet so that an optical communication signal being received and transmitted between two or more of the electronic circuit boards is reflected, shown in FIG. 2, may be provided.

According to the above-mentioned shelf, since the mirror surface is situated at the rear surface of the shelf and the vacant space of the rear surface can be effectively used, it is possible to provide a high quality optical communication path having high reliability at low cost.

As shown in FIG. 6, for example, the mirror surface may have a concave surface at least perpendicular to an arrangement direction of the electronic circuit boards.

Therefore, a signal light generated at both right and left end parts of the shelf can be easily reflected to the center part. In addition, since a space in the shelf center part is made deep, it is possible to drastically decrease directivity (view angle) of the optical transmitting and receiving elements provided at both end parts of the shelf.

The shelf may have a relay member 16 having windows 17 formed as corresponding to positions of optical transmitting and receiving elements of the electronic circuit boards.

Therefore, a high quality optical reflection transmitting path can be formed in a vacant space of the shelf rear surface. Preferably, a mirror surface is provided on the surface of the relay member 16.

In addition, according to the above-discussed embodiment of the present invention, an electronic circuit device, including a plurality of connectors 19 arranged on a back board 12 of a shelf, the shelf having a right hexahedral-shaped configuration; a plurality of electronic circuit boards 21 through 28 detachably supported by the connectors; and a bonnet 13 attached to a front surface opening part of the shelf so as to form a closed space; wherein a mirror surface 18 is provided at a rear surface of the bonnet; and optical transmitting and receiving elements LED and PD are provided at bonnet sides of the electronic circuit boards so that optical communications are performed between two or more of the electronic circuit boards by using light reflected by the mirror surface, shown in FIG. 2, may be provided.

According to the above-mentioned electronic circuit device, since the mirror surface is situated at the rear surface of the shelf and the vacant space of the rear surface can be effectively used, it is possible to transfer a large amount of data between the electronic circuit boards at high speed and low cost. Therefore, it is possible to easily accommodate an increased number of signals transferred or sent among the boards or an increase in the number of boards. In addition, since no electric wire exists at a side of the bonnet, it is possible to easily remove the bonnet even when the device is working so that the mirror surface can be maintained. If necessary, an inoperable electronic circuit board can be removed with minimum effect on the system.

The optical transmitting and receiving elements may be infrared optical transmitting and receiving elements.

Therefore, there is little degradation due to exotic optical noise.

The electronic circuit device may further include a detection part configured to detect opening and closing states of the bonnet; wherein the optical communications between two or more of the electronic circuit boards may be started or stopped in connection with detection of the closing or opening state, respectively, of the bonnet by the detection part.

Therefore, it is possible to perform the maintenance easily and safely.

The electronic circuit boards may include a plurality of monitored circuit boards configured to detect and hold various status signals related to communication control of a system and a monitoring circuit board configured to monitor the plural monitored circuit boards; and the monitoring circuit board may monitor the plural monitored circuit boards by Pauling control via the optical transmitting and receiving element.

Therefore, it is possible to safely perform high level communication control without crosstalk by using a common space of the bonnet rear surface.

The monitoring circuit board may detect the opening and closing states of the bonnet based on existence and non-existence of response in a designated time from the monitored circuit boards.

Therefore, it is possible to easily determine the opening or closing state of the bonnet without separately providing a detection part so that a maintenance operation can be smoothly and safely performed on the device.

Each of the electronic circuit boards may perform the optical communication control between two ore more of the electronic circuit boards using a CSMA/CD method.

Therefore, it is possible to constitute a systematic communications network in plural boards without separately providing a communication control board.

This patent application is based on Japanese Priority Patent Application No. 2006-92853 filed on Mar. 30, 2006, the entire contents of which are hereby incorporated by reference.

What is claimed is:

1. A shelf for receiving a plurality of electronic circuit boards, the electronic circuit boards having a structure where a connecter installing part is provided at a front end part of each of the boards and an optical transmitting and receiving element for optical communications between two or more of the electronic circuit boards is provided at a rear end part of each of the boards, the shelf comprising:
a plurality of connectors arranged on a backboard of the shelf, the shelf having a right hexahedral-shaped configuration, the connectors detachably supporting the connecter installing parts of the electronic circuit boards; and
a bonnet attached to a front surface opening part of the shelf so as to form a closed space, the bonnet having a mirror surface situated at a rear surface of the bonnet so that an optical communication signal being received and transmitted between two or more of the electronic circuit boards is reflected.

2. The shelf for receiving the plural electronic circuit boards as claimed in claim 1;
wherein the mirror surface has a concave surface at least perpendicular to an arrangement direction of the electronic circuit boards.

3. The shelf for receiving the plural electronic circuit boards as claimed in claim 1;
wherein the shelf has a relay member having windows formed as corresponding to positions of optical transmitting and receiving elements of the electronic circuit boards.

4. An electronic circuit device, comprising:
a plurality of connectors arranged on a back board of a shelf, the shelf having a right hexahedral-shaped configuration;
a plurality of electronic circuit boards detachably supported by the connectors; and
a bonnet attached to a front surface opening part of the shelf so as to form a closed space;
wherein a mirror surface is provided at a rear surface of the bonnet; and
optical transmitting and receiving elements are provided at bonnet sides of the electronic circuit boards so that optical communications are performed between two or more of the electronic circuit boards by using light reflected by the mirror surface.

5. The electronic circuit device as claimed in claim 4,
wherein the optical transmitting and receiving elements are infrared optical transmitting and receiving elements.

6. The electronic circuit device as claimed in claim 4, further comprising:
a detection part configured to detect opening and closing states of the bonnet;
wherein the optical communications between two or more of the electronic circuit boards is started or stopped in connection with detection of the closing or opening state, respectively, of the bonnet by the detection part.

7. The electronic circuit device as claimed in claim 6,
wherein the electronic circuit boards includes a plurality of monitored circuit boards configured to detect and hold various status signals related to communication control of a system and a monitoring circuit board configured to monitor the plural monitored circuit boards; and
the monitoring circuit board monitors the plural monitored circuit boards by Pauling control via the optical transmitting and receiving element.

8. The electronic circuit device as claimed in claim 7,
wherein the monitoring circuit board detects the opening and closing states of the bonnet based on existence and non-existence of response in a designated time from the monitored circuit boards.

9. The electronic circuit device as claimed in claim 4,
wherein each of the electronic circuit boards performs the optical communication control between two ore more of the electronic circuit boards using a CSMA/CD method.
